(19) United States
(12) Patent Application Publication
(10) Pub. No.: US 2026/0039302 A1
(43) Pub. Date: Feb. 5, 2026

(54) CONTROLLING A GATE DRIVER WITH A TRISTATE CONTROL SIGNAL

(71) Applicant: MILWAUKEE ELECTRIC TOOL CORPORATION, Brookfield, WI (US)

(72) Inventors: Douglas R. Fieldbinder, Greendale, WI (US); Caleb W. Colbert, Zion, IL (US)

(21) Appl. No.: 19/283,879

(22) Filed: Jul. 29, 2025

Related U.S. Application Data
(60) Provisional application No. 63/679,358, filed on Aug. 5, 2024.

(51) Int. Cl. H03K 19/094; H03K 17/0412

(52) U.S. Cl. CPC H03K 19/09429; H03K 17/04123; H03K 2217/0063; H03K 2217/0072

(57) ABSTRACT

A power tool including a power source, a motor, a bridge circuit connected to the motor, a gate driver connected to the bridge circuit, and a controller connected to the gate drive and configured to provide a tristate control signal to the gate driver. The gate driver is configured to control the bridge circuit to drive the motor based on the tristate control signal.

### CROSS-REFERENCE TO RELATED APPLICATIONS

This application claims priority to, and the benefit of, U.S. Provisional Patent No. 63/679,358 filed Aug. 5, 2024, the contents of which are hereby incorporated by reference.

### SUMMARY

Gate drivers are used to control the actuation of switches, for example, field-effect transistors (FETs). The gate driver may be provided with a pulse width modulation (PWM) signal having a duty ratio that the gate driver uses to control an ON time and an OFF time of the switch. The single switch may be controlled by the gate driver to selectively provide current to a load, for example, the load may be a motor, a voltage converter, and the like. In the case of a direct current (DC) brushless motor, six switches may be used to drive the motor. Traditionally, each of the six switches is controlled by its own gate driver based on a PWM signal provided by a motor controller. Each gate driver takes up space in a tool that could be allocated elsewhere or could allow the tool to be smaller in size. Additionally, the motor controller sends six separate signals to each of the gate drivers to drive the six switches resulting in a complex control scheme. Accordingly, it would be advantageous to minimize the number of gate drivers needed by implementing a controller with tristate output capability and a gate driver that may receive a tristate input signal. The controller outputs a tristate control signal that a gate driver may use to control two switches.

In one embodiment, a power tool includes a power source, a motor, a bridge circuit connected to the motor, a gate driver connected to the bridge circuit, and a controller connected to the gate drive and configured to provide a tristate control signal to the gate driver. The gate driver is configured to control the bridge circuit to drive the motor based on the tristate control signal.

In a further embodiment, an electronic device includes a bridge circuit, a gate driver electrically connected to the bridge circuit, and a controller electrically coupled to the gate driver and configured to provide a tristate control signal to the gate driver. The gate driver is configured to control the bridge circuit based on the tristate control signal.

In an even further embodiment, a power converter device includes a bridge circuit, a gate driver electrically connected to the bridge circuit, and a controller electrically coupled to the gate driver and configured to provide a tristate control signal to the gate driver. The gate driver is configured to control the bridge circuit based on the tristate control signal.

Before any embodiments are explained in detail, it is to be understood that the embodiments are not limited in their application to the details of the configuration and arrangement of components set forth in the following description or illustrated in the accompanying drawings. The embodiments are capable of being practiced or of being carried out in various ways. Also, it is to be understood that the phraseology and terminology used herein are for the purpose of description and should not be regarded as limiting. The use of “including,” “comprising,” or “having” and variations thereof are meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings.

In addition, it should be understood that embodiments may include hardware, software, and electronic components or modules that, for purposes of discussion, may be illustrated and described as if the majority of the components were implemented solely in hardware. However, one of ordinary skill in the art, and based on a reading of this detailed description, would recognize that, in at least one embodiment, the electronic-based aspects may be implemented in software (e.g., stored on non-transitory computer-readable medium) executable by one or more processing units, such as a microprocessor and/or application specific integrated circuits (“ASICs”). As such, it should be noted that a plurality of hardware and software-based devices, as well as a plurality of different structural components, may be utilized to implement the embodiments. For example, “servers,” “computing devices,” “controllers,” “processors,” etc., described in the specification can include one or more processing units, one or more computer-readable medium modules, one or more input/output interfaces, and various connections (e.g., a system bus) connecting the components.

Relative terminology, such as, for example, “about,” “approximately,” “substantially,” etc., used in connection with a quantity or condition would be understood by those of ordinary skill to be inclusive of the stated value and has the meaning dictated by the context (e.g., the term includes at least the degree of error associated with the measurement accuracy, tolerances [e.g., manufacturing, assembly, use, etc.] associated with the particular value, etc.). Such terminology should also be considered as disclosing the range defined by the absolute values of the two endpoints. For example, the expression “from about 2 to about 4” also discloses the range “from 2 to 4”. The relative terminology may refer to plus or minus a percentage (e.g., 1%, 5%, 10%, or more) of an indicated value.

It should be understood that although certain drawings illustrate hardware and software located within particular devices, these depictions are for illustrative purposes only. Functionality described herein as being performed by one component may be performed by multiple components in a distributed manner. Likewise, functionality performed by multiple components may be consolidated and performed by a single component. In some embodiments, the illustrated components may be combined or divided into separate software, firmware and/or hardware. For example, instead of being located within and performed by a single electronic processor, logic and processing may be distributed among multiple electronic processors. Regardless of how they are combined or divided, hardware and software components may be located on the same computing device or may be distributed among different computing devices connected by one or more networks or other suitable communication links. Similarly, a component described as performing particular functionality may also perform additional functionality not described herein. For example, a device or structure that is “configured” in a certain way is configured in at least that way but may also be configured in ways that are not explicitly listed.

Other aspects of the embodiments will become apparent by consideration of the detailed description and accompanying drawings.

### BRIEF DESCRIPTION OF THE DRAWINGS

FIG. 1 illustrates a power tool, according to some embodiments.

FIG. 2 illustrates a battery pack, according to some embodiments.

FIG. 3 illustrates a block diagram of a gate driver circuit, according to some embodiments.

FIG. 4 illustrates a circuit schematic of a first example power tool using the gate driver circuit of FIG. 3, according to some embodiments.

FIG. 5 illustrates a circuit schematic of a second example power tool using the gate driver circuit of FIG. 3, according to some embodiments.

FIG. 6 illustrates a logic and output graph of the gate driver circuit of FIG. 3, according to some embodiments.

FIG. 7 illustrates a segment of a tristate control signal, according to some embodiments.

FIG. 8 illustrates a block diagram of the power tool of FIG. 1, according to some embodiments.

FIG. 9 illustrates a flowchart of a method for outputting a tristate control signal to a gate driver, according to some embodiments.

### DETAILED DESCRIPTION

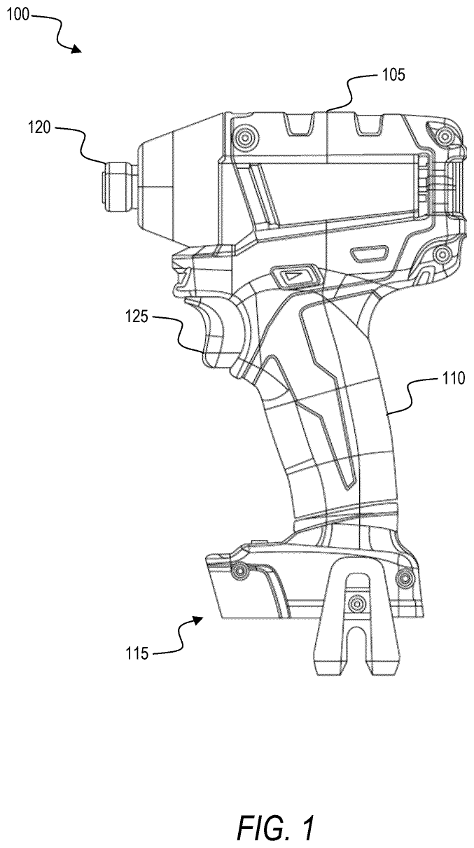

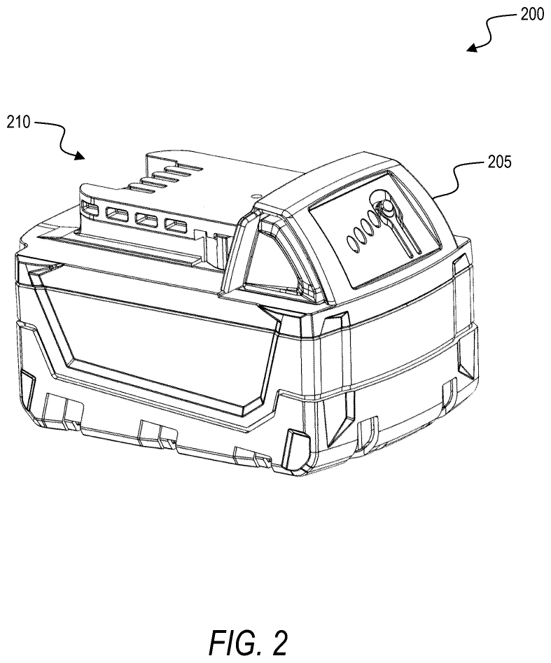

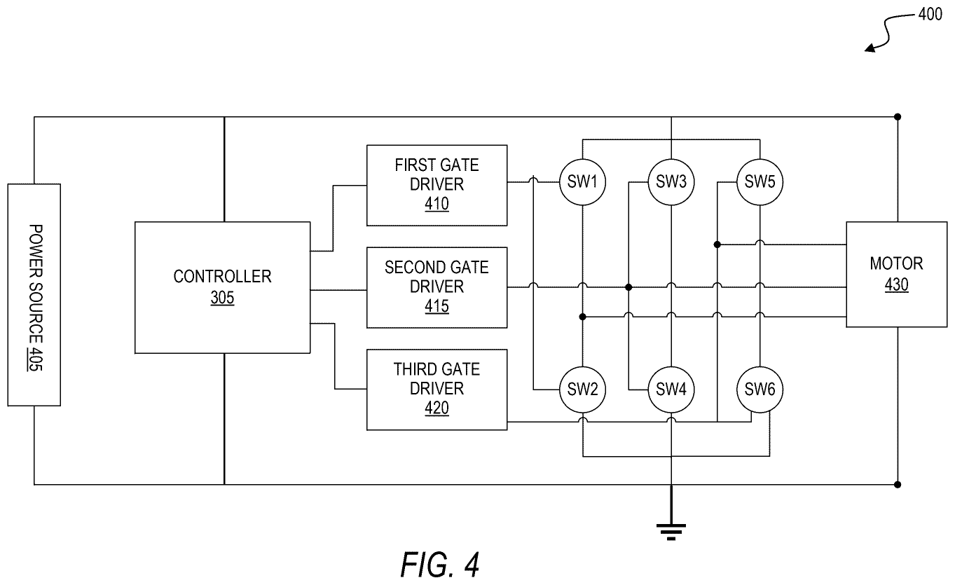

FIG. 1 illustrates an embodiment of a power tool 100 (e.g., electronic device) including a brushless direct current (“BLDC”) motor. The power tool 100 is, for example, an impact driver including an upper main body 105, a handle 110, a battery pack receiving portion 115, an output drive device or mechanism 120, and a trigger 125. The power tool 100 further includes a motor, such as motor 430 (FIG. 4) within the main body 105 of the housing and having a rotor and a stator. The rotor is coupled to a motor shaft arranged to produce an output outside of the housing via the output drive device or mechanism 120. The housing of the power tool 100 (e.g., the main body 105 and the handle 110) are composed of a durable and light-weight plastic material. The drive device 108 is composed of a metal (e.g., steel) output spindle. The battery pack receiving portion 115 is configured to receive and couple to a battery pack, such as a battery pack 200 (FIG. 2) that provides power to the power tool 100. The battery pack receiving portion 115 includes a connecting structure to engage a mechanism that secures the battery pack and a terminal block to electrically connect the battery pack 200 to the power tool 100. In some embodiments, the power tool 100 may be an alternating current (AC) powered power tool that includes a rectifier to provide a DC voltage to the motor 430.

FIG. 1 illustrates an impact wrench, however, the power tool 100 may include drills, circular saws, jig saws, band saws, reciprocating saws, screw drivers, angle grinders, straight grinders, hammers, multi-tools, impact wrenches, rotary hammers, impact drivers, angle drills, powered ratchets, powered torque wrenches, hydraulic pulse tools, hydraulic tensioning tools, lock bolt installation tools, reaction arm tools, riveting tools, nailers, staplers, TC bolt guns, and the like. In some examples, the electronic device may include a portable power source that includes an internal battery module or that may receive battery packs (e.g., battery pack 200) and includes an AC outlet to power AC electronic devices. In the example of the portable power source, the motor is replaced with the AC outlet, however, the operation described below is equally applicable.

FIG. 2 illustrates a battery pack 200, according to some embodiments. The battery pack 200 is a power tool battery pack that is generally used to power a power tool, such as the power tool 100. The battery pack 200 includes a housing 205 and an interface portion 210 for connecting the battery pack 200 to a device (e.g., the power tool 100). In some embodiments, the battery pack 200 includes lithium ion battery cells. In other embodiments, the battery pack 200 may be of a different chemistry, for example, nickel-cadmium, nickel-metal hydride, and the like. In the illustrated embodiment, the battery pack 200 is an 18 volt battery pack. In other embodiments, the output voltage level of the battery pack 200 may be different. For example, the battery pack 200 can be a 4 volt battery pack, 28 volt battery pack, 36 volt battery pack, 72 volt battery pack or another voltage (voltage here may refer to nominal voltage). The battery pack 200 may also have various capacities (e.g., 3, 4, 5, 6, 8, or 12 ampere-hours).

The battery pack 200 also includes terminals to connect to the power tool 100. The terminals for the battery pack 200 includes a positive and a negative terminal to provide power to and from the battery pack 200. In some embodiments, the battery pack 200 also includes data terminals to communicate with the power tool 100. For example, the battery pack 200 may include a microcontroller to monitor one or more characteristics of the battery pack 200 and the data terminals may communicate with the power tool 100 regarding the monitored characteristics.

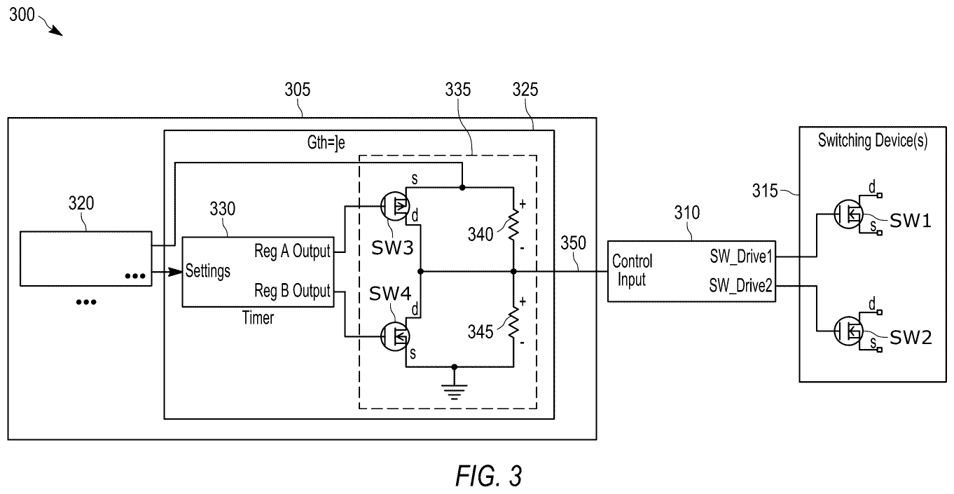

FIG. 3 is a block diagram of a gate driver circuit 300. The gate driver circuit 300 may be used in a power tool, for example, power tool 100, a voltage converting unit, for example, a buck/boost converter, power supplies, and the like. The gate driver circuit 300 includes a controller 305, a gate driver 310 and a bridge circuit 315. The controller 305 outputs a tristate control signal to the gate driver 310 which uses the tristate control signal to drive both a first switch SW1 and a second switch SW 2 of the bridge circuit 315. For example, the switches SW1, SW2 may be a field effect transistor (FET), such as a metal oxide semiconductor FET (MOSFET), a wide bandgap semiconductor FET, a bipolar junction transistor (BJT), or the like and the first switch SW1 may be a high side switch and the second switch SW2 may be a low side switch that corresponds to the high side switch. The switches SW1, SW2 drive a load, for example, a motor. The tristate control signal may be a tristate pulse width modulation (PWM) signal. Typically control signals include only two states, e.g., high state corresponding to source voltage (or input voltage) and low state corresponding to ground voltage. The tristate control signal includes three states corresponding to three different voltages, for example, a high state corresponding to the source voltage, a low state corresponding to ground voltage, and a middle state corresponding to a fraction of (e.g., half) the source voltage.

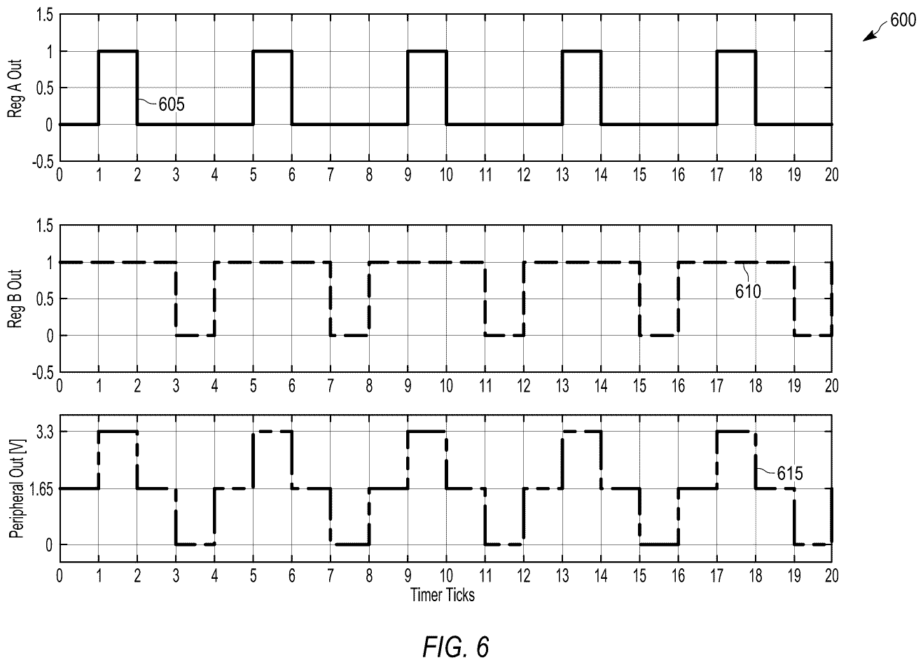

The controller 305 may include a voltage source 320 and a timing unit 325. The timing unit 325 includes a timer 330 and a timing circuit 335 including a third switch SW3, a fourth switch SW4, a first resistor 340, and a second resistor 345. The switches SW3, SW4 may be MOSFETS, wide bandgap FETs, BJTs, or the like. The first resistor 340 and the second resistor 345 may be equal in value to together form a voltage divider. The switches SW3 and SW4 are connected in parallel to the first resistor 340 and the second resistor 345 between the voltage source 320 and ground. That is, the third switch SW3 and the first resistor 340 are connected in parallel between the voltage source 320 and a tristate control output 350. The fourth switch SW4 and the second resistor 345 are connected in parallel between the tristate control output and ground. The voltage source 320 may output a constant first voltage value, for example, 3.3 volts, to the timing circuit 335. The timer 330 may control the third switch SW3 and the fourth switch SW4 using a first switch signal and a second switch signal to provide the tristate control signal through the tristate control output 350, respectively. The switch signals will be described below with respect to FIG. 6. The timer 330 may control the switches SW3, SW4 based on input from an actuator. For example, a user may actuate the trigger 125 of the power tool 100 and the controller 305 may send a signal to the timer 330 to control the switches SW3, SW4 to provide a tristate control signal to the gate driver 310 to drive a load. The timer 330 may include two registers (e.g., register A and register B) corresponding to each of the switches SW3, SW4. The timer 330 may receive a setting signal that controls the registers A, B to provide the switch signals as described below with respect to FIG. 6.

The timer 330 controls the third switch SW3 and the fourth switch SW4 to provide the tristate control signal via the tristate control output 350 to the gate driver 310. For example, the voltage source 320 may provide the first voltage value (e.g., 3.3 volts) to the timing circuit 335 and the timer 330. A voltage signal output to the gate driver 310 from the timing circuit 335 may be the tristate control signal with a second voltage value, a third voltage value, and a fourth voltage value. The first voltage is transformed into the tristate control signal based on the state of the third switch SW3 and the fourth switch SW4. For example, when the third switch SW3 and the fourth switch SW4 are open, the first resistor 340 and the second resistor 345 act as a voltage divider to divide the input voltage (e.g., 3.3. volts) to provide the divided voltage (e.g., 1.65 Volts when the first resistor 340 and second resistor 345 are of approximately equal value) as the tristate control signal. When the third switch SW3 is closed and the fourth switch SW4 is open, the timing circuit 335 bypasses the first resistor 340 and connects the tristate control output 350 to the voltage source 320 thereby providing the input voltage (e.g., 3.3 volts) as the tristate control signal. When the third switch SW3 is open and the fourth switch SW4 is closed, the timing circuit 335 bypasses the second resistor 345 and connects the tristate control output 350 to ground thereby providing ground voltage (e.g., 0 Volts) as the tristate control signal. The voltage outputs to the gate driver 310 is provided below in Table 1 based on the states of the third switch SW3 and the fourth switch SW4.

TABLE 1

| | | | Voltage |
|---|---|---|---|
| | State | State | Output |
| | of | of | to |
| | the | the | the |
| | Third | Fourth | Gate |
| | Switch | Switch | driver |
| | SW | SW | 310 |
| | 3 | 4 | (V) |
| First Scenario | OFF | OFF | 1.65 |
| Second Scenario | ON | OFF | 3.3 |
| Third Scenario | OFF | ON | 0 |

The gate driver 310 includes an input interface that accepts a tristate input. For example, the gate driver 310 may be implemented using, for example, an Infineon part no. TDA 21590, an OnSemi part no. NCP5111, a Monolithic Power Systems part no. MP18871 or MP86885, a Texas Instruments part no. CSD95485, TPS53647, or CSD955472Q5MC, or a STMicro part no. PM7080.

FIG. 4 is a circuit schematic of a first example power tool 400. The first example power tool 400 may be the power tool 100 of FIG. 1 that includes a BLDC motor. The first example power tool 400 includes a power source 405, the controller 305, a first gate driver 410, a second gate driver 415, a third gate driver 420, first through sixth switches SW1-SW6 (e.g., a bridge circuit), and the BLDC motor 430. In the example illustrated, the first through sixth switches SW1-SW6 form an inverter bridge to convert the DC power from the power source 405 to AC power to drive the motor 430. In other examples, the inverter bridge may be used to convert DC to AC (e.g., three-phase AC) for other electronic devices (e.g., for portable power sources). The motor 430 is driven by the switches SW1-SW6. The power source 405 may be the battery pack 200. The controller 305 may include multiple timing units 325 that each correspond to a gate driver. Alternatively, the timing unit 325 may provide an output to each gate driver.

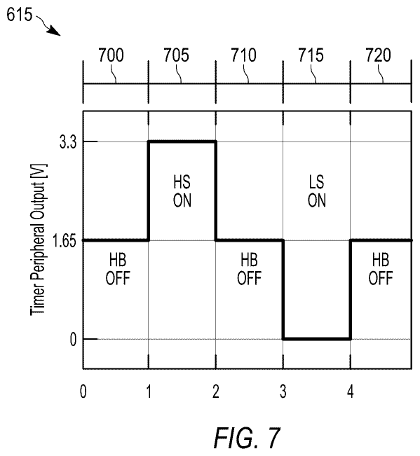

The first gate driver 410 controls the first switch SW1 and the second switch SW2. The second gate driver 415 controls the third switch SW 3 and the fourth switch SW4. The third gate driver 415 controls the fifth switch SW5 and the sixth switch SW6. The first switch SW1, the third switch SW3, and the fifth switch SW5 are high-side switches and the second switch SW2, the fourth switch SW4, and the sixth switch SW6 are low-side switches. Control of the switches SW1-SW6 using the tristate control signal will be described below with respect to FIG. 7.

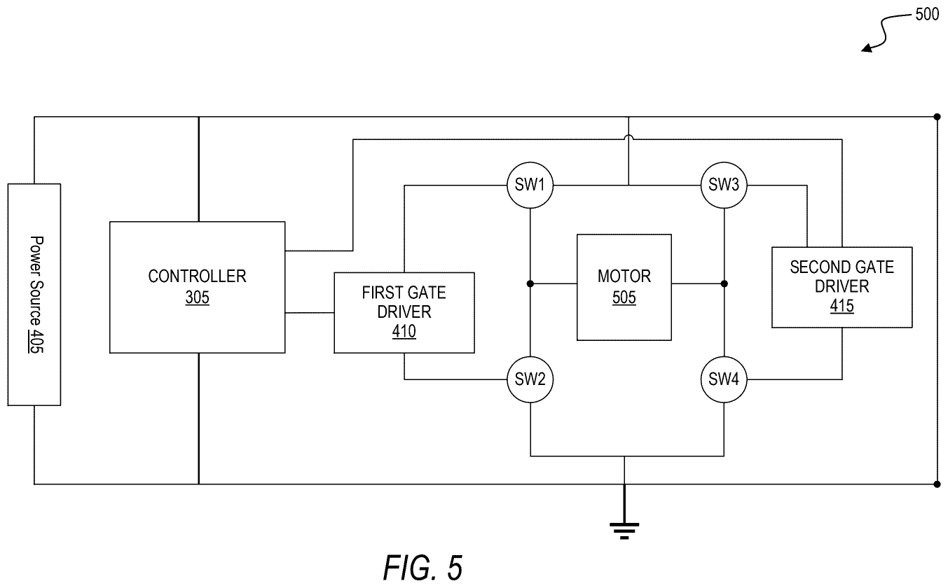

FIG. 5 is a circuit schematic of a second example power tool 500. The second example power tool 500 may be a power tool that includes a DC motor that is driven by an H-bridge. The second example power tool 500 includes the power source 405, the controller 305, the first gate driver 410, the second gate driver 415, first through fourth switches SW1-SW4 (e.g., a bridge circuit), and the DC motor 505. In the example illustrated, the first through fourth switches SW1-SW4 form an H-bridge to drive the motor 430. In other examples, the H-bridge may be used to convert DC to AC (e.g., single phase AC) for other electronic devices (e.g., for portable power sources). The motor 505 is driven by the switches SW1-SW4.

The first gate driver 410 controls the first switch SW1 and the second switch SW2. The second gate driver 415 controls the third switch SW 3 and the fourth switch SW4. For example, based on the tristate control signal received by the first switch device driver 410, the first switch device driver 410 controls the first switch SW1 and the second switch SW2 to control a first polarity of the motor 505 and the second switch device driver 415 controls the third switch SW3 and the fourth switch SW4 to control a second polarity of the motor 505.

FIG. 6 is a logic and output graph 600 of the gate driver circuit 300. The logic and output graph 600 includes a first switch signal 605, a second switch signal 610, and a tristate control signal 615. With reference to FIG. 3, the first switch signal 605 is provided from the timer 330 to the third switch SW3 of the timing circuit 335, the second switch signal 610 is provided from the timer 330 to the fourth switch SW4 of the timing circuit 335, and the tristate control signal 615 is provided from the timing unit 325 to the gate driver 310. For purposes of this example, the third switch SW3 is a p-channel enhancement mode MOSFET that is activated (i.e., closed) when a high signal is provided at the gate and the fourth switch SW4 is an n-channel enhancement mode MOSFET that is activated (i.e., closed) when a low signal is provided at the gate.

As discussed above with respect to TABLE 1, when both switches SW3 and SW4 are open, e.g., between timer ticks 0-1 when the first switch signal 605 is low and the second switch signal 610 is high, the tristate control signal 615 is 1.65 Volts. When the third switch SW3 is closed and SW4 is open, e.g., between timer ticks 1-2 when the first switch signal 605 and the second switch signal 610 are high, the tristate control signal 615 is 3.3 Volts. When the third switch SW3 is open and the fourth switch SW4 is closed, e.g., between timer ticks 3-4 when the first switch signal 605 is low and the second switch signal 610 is low, the tristate control signal 615 is 0 Volts.

FIG. 7 is a segment of the tristate control signal 615 described with respect to the gate driver circuit 300 (FIG. 3). For example, the tristate control signal 615 is used to control the bridge circuit 315 coupled to the gate driver 310. During the first time segment 700, the tristate control signal 615 is at a first state. For example, the first state may be at the second voltage value (e.g., 1.65 volts). When the tristate control signal 615 is at the first state, the gate driver 310 control both the switches SW1, SW2 of the bridge circuit 315 to be OFF.

During the second time segment 705, the tristate control signal 615 is at a second state. For example, the second state may be at the third voltage value (e.g., 3.3 volts). When the tristate control signal 615 is at the second state, the gate driver 310 controls the high-side switch SW1 to be ON and the low-side switch SW2 to be OFF. During the third time segment 710, the tristate control signal 615 is at the first state and the gate driver 310 controls both the switches SW1, SW2 of the bridge circuit 315 to be OFF.

During the fourth time segment 715, the tristate control signal 615 is at a fourth state. For example, the fourth state may be at the fourth voltage value (e.g., 0 volts). When the tristate control signal 615 is at the fourth state, the gate driver 310 control the low-side switch SW2 to be ON and the high-side switch SW1 to be OFF. During the fifth time segment 720, the tristate control signal 615 is at the first state and the gate driver 310 controls both the switches SW1, SW2 of the bridge circuit 315 to be OFF. This control may be used for driving a motor or converting DC current to AC current in the power tools 400, 500, the portable power source, or the like

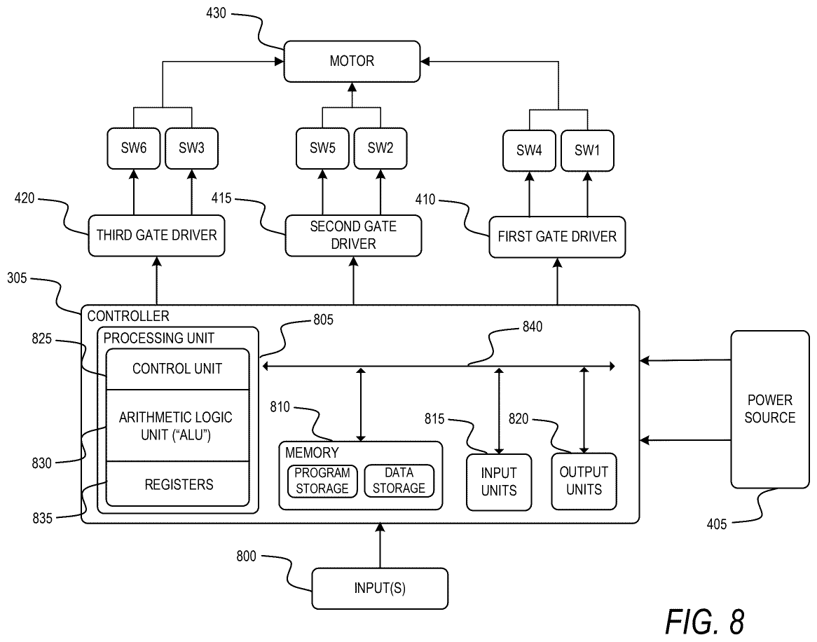

FIG. 8 is a schematic illustration of the controller 305 of a device including the gate driver circuit 300. For example, the controller 305 may include the voltage source 320 and the timing unit 325 (both not shown in FIG. 8) and be provided in the power tool 100. The controller 305 is electrically and/or communicatively connected to a variety of modules or components of the device. Though specifically described below with respect to the power tool 100, the controller 305 may be provided any device including the gate driver circuit 300. The illustrated controller 305 may be connected to inputs 800, the power source 405, the first gate driver 410, the second gate driver 415, and the third gate driver 420. The power source 405 may include, for example, the battery pack 200, internal battery cores (e.g., non-removable) including stacks of series and/or parallel connected battery cells, and the like.

The controller 305 includes combinations of hardware and software that are operable to, among other things, control the operation of the power tool 100. For example, the controller 305 includes, among other things, a processing unit 805 (e.g., a microprocessor, a microcontroller, an electronic processor, an electronic controller, or another suitable programmable device), a memory 810, input units 815, and output units 820. The processing unit 805 includes, among other things, a control unit 825, an arithmetic logic unit (“ALU”) 830, and a plurality of registers 835 (shown as a group of registers in FIG. 8) and is implemented using a known computer architecture (e.g., a modified Harvard architecture, a von Neumann architecture, etc.). The processing unit 805, the memory 810, the input units 815, and the output units 820, as well as the various modules or circuits connected to the controller 305 are connected by one or more control and/or data buses (e.g., common bus 840). The control and/or data buses are shown generally in FIG. 8 for illustrative purposes. Although the controller 305 is illustrated in FIG. 8 as one controller, the controller 305 could also include multiple controllers configured to work together to achieve a desired level of control for the power tool 100. As such, any control functions and processes described herein with respect to the controller 305 could also be performed by two or more controllers functioning in a distributed manner. For example, each gate driver may have its own controller.

The memory 810 is a non-transitory computer readable medium and includes, for example, a program storage area and a data storage area. The program storage area and the data storage area can include combinations of different types of memory, such as a read only memory (“ROM”), a random access memory (“RAM”) (e.g., dynamic RAM [“DRAM”], synchronous DRAM [“SDRAM”], etc.), electrically-erasable programmable ROM (“EEPROM”), flash memory, a hard disk, an SD card, or other suitable magnetic, optical, physical, or electronic memory devices. The processing unit 805 is connected to the memory 810 and is configured to execute software instructions that are capable of being stored in a RAM of the memory 810 (e.g., during execution), a ROM of the memory 810 (e.g., on a generally permanent basis), or another non-transitory computer readable medium such as another memory or a disc. Software included in the implementation of the power tool 100 and controller 305 can be stored in the memory 810 of the controller 305. The software includes, for example, firmware, one or more applications, program data, filters, rules, one or more program modules, and other executable instructions. The controller 305 is configured to retrieve from the memory 810 and execute, among other things, instructions related to the control processes and methods described herein. In other embodiments, the controller 305 includes additional, fewer, or different components.

The inputs 800 may include a trigger switch coupled to the trigger 125, an ON/OFF switch coupled to a power actuator, a speed selections switch coupled to a speed selector, a current sensor, a voltage sensor, a temperature sensor, and the like. Based on input from the inputs 800, the controller 305 may control the gate drivers 410, 415, 420 to drive the load. For example, when a user depresses the trigger 125, a trigger switch may provide an input to the controller 305 that the controller uses to control the gate drivers 410, 415, 420 to drive the motor 430 based on the level of depression of the trigger 125. The controller controls the gate drivers 410, 415, 420 using a tristate control signal as described above.

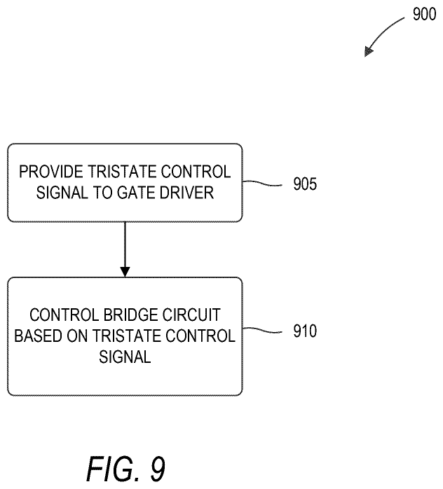

FIG. 9 illustrates a flowchart of a method 900 for outputting a tristate control signal 615 to a gate driver 310. Although the illustrated method 900 includes specific steps, not all of the steps need to be performed or need to be performed in the order presented. The method 900 may be executed by the gate driver circuit 300 (e.g., the controller 305 of the power tool 100).

The method 900 includes providing a tristate control signal 615 to a gate driver 310 (step 905). The tristate control signal may be provided from the controller 305 to the gate driver 310. For example, the controller 305 may control the voltage source 320 to provide a first voltage value to the timer 330 and the timing circuit 335. The controller may control switches of the timing circuit 335 using the first switch signal 605 and the second switch signal 610. For example, the controller may control the third switch SW3 with the first switch signal 605 and the fourth switch SW4 with the second switch signal 610 as described above with respect to FIG. 6.

The method 900 includes controlling a bridge circuit 315 based on the tristate control signal 615 (step 910). The tristate control signal 615 includes at least four states as described above with respect to FIG. 6. For example, in a first state the gate driver 310 control both the switches SW1, SW2 of the bridge circuit 315 to be OFF, in a second state the gate driver 310 controls the high-side switch SW1 to be ON and the low-side switch SW2 to be OFF, in a third state the gate driver 310 controls both the switches SW1, SW2 of the bridge circuit 315 to be OFF, and in a fourth state the gate driver 310 control the low-side switch SW2 to be ON and the high-side switch SW1 to be OFF. The bridge circuit 315 may be controlled for driving a motor or converting DC current to AC current in the power tools 400, 500, the portable power source, or the like.

Thus, embodiments described herein provide, among other things, systems and methods for providing a gate driver with a tristate control signal to control a bridge circuit.

What is claimed is:

1. A power tool comprising:
a power source;
a motor;
a bridge circuit connected to the motor;
a gate driver connected to the bridge circuit; and
a controller connected to the gate driver and configured to provide a tristate control signal to the gate driver,
wherein the gate driver is configured to control the bridge circuit to drive the motor based on the tristate control signal.

2. The power tool of claim 1, wherein the tristate control signal includes a first control state, a second control state, and a third control state.

3. The power tool of claim 2, wherein the gate driver is configured to:
control a first switch and a second switch of the bridge circuit to be off when the tristate control signal is in the first control state,
control the first switch of the bridge circuit to be on and the second switch of the bridge circuit to be off when the tristate control signal is in the second control state, and
control the first switch of the bridge circuit to be off and the second switch of the bridge circuit to be on when the tristate control signal is in the third control state.

4. The power tool of claim 1, wherein the controller includes a voltage source, a timer, and a first circuit.

5. The power tool of claim 4, wherein a first output of the voltage source is coupled to the timer, wherein a second output of the voltage source is coupled to the first circuit, wherein an output of the timer is coupled to the first circuit, and wherein an output of the first circuit is coupled to the gate driver.

6. The power tool of claim 4, wherein the first circuit includes a first switch connected in parallel with a second switch, and wherein the gate driver is connected between the first switch and the second switch.

7. The power tool of claim 6, wherein the controller is configured to:
control, using an output of the timer, the first switch and the second switch in a first state,
wherein a first voltage is provided to the gate driver in response to the first switch and the second switch being in the first state.

8. The power tool of claim 7, wherein the controller is configured to:
control, with the timer, the first switch in a second state and the second switch in the first state,
wherein a second voltage, greater than the first voltage, is provided to the gate driver in response to the first switch being in the second state and the second switch being in the first state.

9. The power tool of claim 8, wherein the controller is configured to:
control, with the timer, the first switch in the first state and the second switch in the second state,
wherein a third voltage, less than the first voltage, is provided to the gate driver in response to the first switch being in the first state and the second switch being in the second state.

10. An electronic device comprising:
a bridge circuit;
a gate driver electrically connected to the bridge circuit; and
a controller electrically coupled to the gate driver and configured to provide a tristate control signal to the gate driver,
wherein the gate driver is configured to control the bridge circuit based on the tristate control signal.

11. The electronic device of claim 10, wherein the gate driver is configured to control a first plurality of switches in the bridge circuit based on a first tristate control signal.

12. The electronic device of claim 11 further comprising:
a second gate driver connected to the bridge circuit, wherein the second gate driver is configured to control a second plurality of switches in the bridge circuit based on a second tristate control signal.

13. The electronic device of claim 12, wherein the first plurality of switches and the second plurality of switches form an H-bridge.

14. The electronic device of claim 12 further comprising:
a third gate driver connected to the bridge circuit, wherein the third gate driver is configured to control a third plurality of switches in the bridge circuit based on a third tristate control signal.

15. The electronic device of claim 14, wherein the controller includes a voltage source with a first output coupled to a timer and a second output coupled to a first circuit, wherein an output of the timer is coupled to the first circuit, and wherein an output of the first circuit is coupled to the gate driver.

16. A power converter device comprising:
a bridge circuit;
a gate driver electrically connected to the bridge circuit; and
a controller electrically coupled to the gate driver and configured to provide a tristate control signal to the gate driver,
wherein the gate driver is configured to control the bridge circuit based on the tristate control signal.

17. The power converter device of claim 16 further comprising:
a power source providing DC input power to the controller,
wherein the gate driver is configured to control the bridge circuit to provide AC output power to a load.

18. The power converter device of claim 16, wherein the controller includes a voltage source, a timer, a first switch, and a second switch.

19. The power converter device of claim 18, wherein the first switch is in a first state and the second switch is in a second state during a first control state of the tristate control signal, wherein the first switch is in the first state and the second switch is in the first state during a second control state of the tristate control signal, and wherein the first switch is in the second state and the second switch is in the first state during a third control state of the tristate control signal.

20. The power converter device of claim 19, wherein the first control state corresponds to a first voltage, wherein the second control state corresponds to a second voltage, greater than the first voltage, and wherein the third control state corresponds to a third voltage, greater than the second voltage.
